(19) United States
(12) Patent Application Publication
(10) Pub. No.: US 2026/0324467 A1
(43) Pub. Date: Oct. 15, 2026

(54) ELECTRONIC PACKAGE STRUCTURE AND METHOD FOR MANUFACTURING THE SAME

(71) Applicant: Advanced Semiconductor Engineering, Inc., Kaohsiung (TW)

(72) Inventors: Cheng-Lan LIN, Kaohsiung (TW); Guo-Cheng LIAO, Kaohsiung (TW)

(73) Assignee: Advanced Semiconductor Engineering, Inc., Kaohsiung (TW)

(21) Appl. No.: 19/177,323

(22) Filed: Apr. 11, 2025

(51) Int. Cl. H01L 23/498; H01L 21/48; H01L 21/56; H01L 23/00; H01L 23/31; H01L 23/367; H01L 23/538; H01L 25/03; H01L 25/18; H10B 80/00; H10D 80/30

(52) U.S. Cl. CPC H10W 70/65; H10W 40/228; H10W 42/121; H10W 70/611; H10W 70/66; H10W 90/401; H10B 80/00; H10D 80/30; H10W 70/02; H10W 70/099; H10W 74/01; H10W 74/117; H10W 74/15; H10W 90/00; H10W 90/724; H10W 90/734

(57) ABSTRACT

An electronic package structure includes an encapsulant, an interconnection element, a first metal material and a second metal material. The interconnection element is disposed in the encapsulant. A top surface of the interconnection element is not level with a top surface of the encapsulant. The first metal material is disposed on the top surface of the interconnection element. The second metal material is conformally disposed on the first metal material.

### BACKGROUND

### 1. Field of the Disclosure

The present disclosure relates to an electronic package structure and a manufacturing method, and to an electronic package structure including an interconnection element and a method for manufacturing the electronic package structure.

### 2. Description of the Related Art

During an operation of an electronic package structure, the heat generated by a semiconductor die or a semiconductor chip in the electronic package structure may adversely affect the performance of the electronic package structure. However, the semiconductor die or the semiconductor chip may be encapsulated in an encapsulant such as a molding compound with a relatively low thermal conductivity. Thus, a heat dissipation is a critical issue. Additionally, the encapsulated semiconductor die or chip is becoming thicker, which makes the extended electrical path around it a significant concern.

### SUMMARY

In some embodiments, an electronic package structure includes an encapsulant, an interconnection element, a first metal material and a second metal material. The interconnection element is disposed in the encapsulant. A top surface of the interconnection element is not level with a top surface of the encapsulant. The first metal material is disposed on the top surface of the interconnection element. The second metal material is conformally disposed on the first metal material.

In some embodiments, an electronic package structure includes an encapsulant, an interconnection element, a first metal material, a second metal material and a solder material. The interconnection element is disposed in the encapsulant, and is bent. The first metal material is disposed on an upper portion of the interconnection element. The second metal material is conformally disposed on the first metal material. The solder material is disposed on the second metal material.

In some embodiments, an electronic package structure includes an encapsulant, an interconnection element and an upper substrate. The interconnection element is disposed in the encapsulant. The upper substrate is disposed over the interconnection element, and includes an outer bond pad. A center of the outer bond pad is misaligned with a center of a top surface of the interconnection element in a direction perpendicular to a top surface of the encapsulant.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of an electronic package structure according to some embodiments of the present disclosure.

FIG. 2 illustrates an enlarged view of an area “A” of FIG. 1.

FIG. 3 illustrates a cross-sectional view of an electronic package structure according to some embodiments of the present disclosure.

FIG. 4 illustrates an enlarged view of an area “B” of FIG. 3.

FIG. 5 illustrates a cross-sectional view of an electronic package structure according to some embodiments of the present disclosure.

FIG. 6 illustrates an enlarged view of an area “C” of FIG. 5.

FIG. 7 illustrates a cross-sectional view of an electronic package structure according to some embodiments of the present disclosure.

FIG. 8 illustrates an enlarged view of an area “D” of FIG. 7.

FIG. 9 illustrates a cross-sectional view of an electronic package structure according to some embodiments of the present disclosure.

FIG. 10 illustrates one or more stages of an example of a method for manufacturing an electronic package structure according to some embodiments of the present disclosure.

FIG. 11 illustrates one or more stages of an example of a method for manufacturing an electronic package structure according to some embodiments of the present disclosure.

FIG. 12 illustrates one or more stages of an example of a method for manufacturing an electronic package structure according to some embodiments of the present disclosure.

FIG. 13 illustrates one or more stages of an example of a method for manufacturing an electronic package structure according to some embodiments of the present disclosure.

FIG. 14 illustrates one or more stages of an example of a method for manufacturing an electronic package structure according to some embodiments of the present disclosure.

FIG. 15 illustrates one or more stages of an example of a method for manufacturing an electronic package structure according to some embodiments of the present disclosure.

FIG. 16 illustrates one or more stages of an example of a method for manufacturing an electronic package structure according to some embodiments of the present disclosure.

FIG. 17 illustrates one or more stages of an example of a method for manufacturing an electronic package structure according to some embodiments of the present disclosure.

FIG. 18 illustrates one or more stages of an example of a method for manufacturing an electronic package structure according to some embodiments of the present disclosure.

FIG. 19 illustrates one or more stages of an example of a method for manufacturing an electronic package structure according to some embodiments of the present disclosure.

FIG. 20 illustrates one or more stages of an example of a method for manufacturing an electronic package structure according to some embodiments of the present disclosure.

FIG. 21 illustrates one or more stages of an example of a method for manufacturing an electronic package structure according to some embodiments of the present disclosure.

FIG. 22 illustrates one or more stages of an example of a method for manufacturing an electronic package structure according to some embodiments of the present disclosure.

FIG. 23 illustrates one or more stages of an example of a method for manufacturing an electronic package structure according to some embodiments of the present disclosure.

FIG. 24 illustrates an enlarged view of an area “E” of FIG. 23.

FIG. 25 illustrates one or more stages of an example of a method for manufacturing an electronic package structure according to some embodiments of the present disclosure.

FIG. 26 illustrates one or more stages of an example of a method for manufacturing an electronic package structure according to some embodiments of the present disclosure.

FIG. 27 illustrates an enlarged view of an area “F” of FIG. 26.

FIG. 28 illustrates one or more stages of an example of a method for manufacturing an electronic package structure according to some embodiments of the present disclosure.

FIG. 29 illustrates one or more stages of an example of a method for manufacturing an electronic package structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

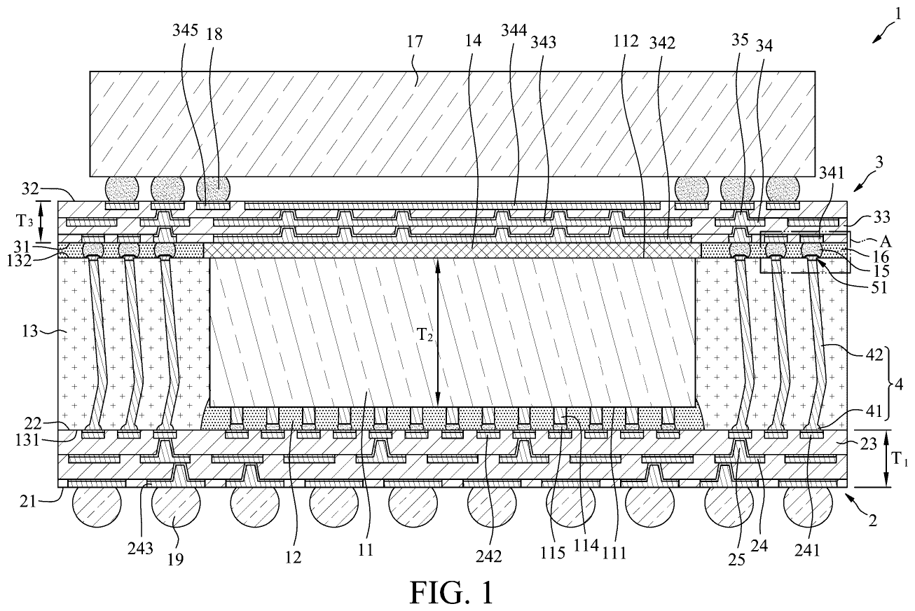

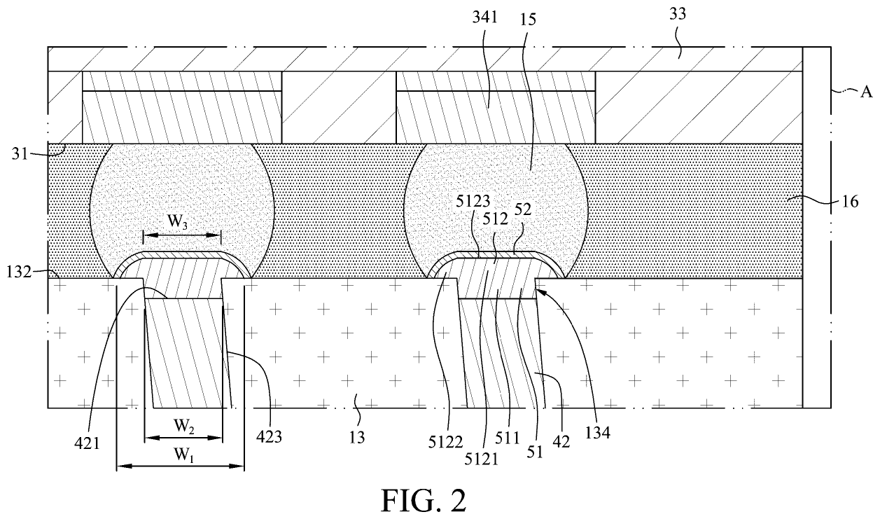

FIG. 1 illustrates a cross-sectional view of an electronic package structure 1 according to some embodiments of the present disclosure. FIG. 2 illustrates an enlarged view of an area “A” of FIG. 1. The electronic package structure 1 may include a lower substrate 2, a first electronic component 11, at least one interconnection element 4, an encapsulant 13, a first metal material 51, a second metal material 52, an upper substrate 3, a heat dissipation structure 14, at least one solder material 15, a protection material 16, a second electronic component 17, at least one connecting element 18 and at least one external connector 19.

The lower substrate 2 may be a first substrate, a circuit pattern structure, a redistribution layer (RDL) structure, a wiring structure or a substrate structure, and may be disposed on a bottom surface 131 of the encapsulant 13. The lower substrate 2 may have a first surface 21 (e.g., a bottom surface) and a second surface 22 (e.g., a top surface) opposite to the first surface 21. The lower substrate structure 2 may include at least one dielectric layer 23, at least one circuit layer 24 (or a redistribution layer) and at least one inner via 25. As shown in FIG. 1, the lower substrate 2 may include three dielectric layers 23, three circuit layers 24 and a plurality of inner vias 25. However, the amount of the dielectric layers 23 and the amount of the circuit layers 24 are not limited in the present disclosure.

The dielectric layer 23 may be made of a cured photoimageable dielectric (PID) material such as epoxy or polyimide (PI) including photoinitiators. The dielectric layers 23 may cover the circuit layers 24, and may be stacked on one another. The inner vias 25 may connect the circuit layers 24. The inner via 25 may taper upward. The inner via 25 may taper toward the first electronic component 11. Thus, a width of the inner via 25 may decrease upward. A tapering direction of the inner via 25 of the lower substrate 2 may be the same as a tapering direction of the inner via 35 of the upper substrate 3. The circuit layer 24 may include a seed layer and a conductive layer disposed on the seed layer. In some embodiments, the seed layer may be omitted.

The topmost circuit layer 24 may include at least one outer pad 241 and at least one inner pad 242 exposed by a topmost one of the dielectric layers 23. A top surface of the outer pad 241 and a top surface of the inner pad 242 may be substantially coplanar with or aligned with a top surface of the topmost dielectric layer 23 (i.e., the second surface 22 (the top surface) of the lower substrate 2). In addition, the bottommost circuit layer 24 may include at least one bottom pad 243 exposed by a bottommost one of the dielectric layers 23. A bottom surface of the bottom pad 243 may be substantially coplanar with or aligned with a bottom surface of the bottommost dielectric layer 23 (i.e., the first surface 21 (the bottom surface) of the lower substrate 2). In some embodiments, the lower substrate 2 may have a first thickness T₁. For example, the first thickness T₁ may be about 110 μm to 120 μm.

The first electronic component 11 may be disposed over the second surface 22 of the lower substrate 2. The first electronic component 11 may be bonded to the lower substrate 2, and electrically connected to the circuit layer 24 of the lower substrate 2. The first electronic component 11 may be encapsulated by the encapsulant 13. The first electronic component 11 may be a semiconductor device such as an application specific integrated circuit (ASIC) die or a high bandwidth memory (HBM) die. The first electronic component 11 may have a bottom surface 111 (e.g., an active surface), a top surface 112 (e.g., a backside surface) opposite to the bottom surface 111, and a lateral surface extending between the top surface 112 and the bottom surface 111. The first electronic component 11 may include a plurality of electrical contacts 114. The electrical contacts 114 may be disposed adjacent to the bottom surface 111 (e.g., the active surface) of the first electronic component 11. The electrical contacts 114 may be exposed or may protrude from the bottom surface 111 (e.g., the active surface) for electrical connection. The electrical contacts 114 may be pads, bumps, studs, pillars or posts. In some embodiments, the electrical contacts 114 of the first electronic component 11 may be electrically connected to and physically connected to the inner pads 242 of the lower substrate 2 through a plurality of solder materials 115. In other words, the first electronic component 11 may be electrically connected to the lower substrate 2 by flip-chip bonding.

As shown in FIG. 1, the first electronic component 11 may be disposed between the upper substrate 3 and the lower substrate 2. An underfill 12 may be further included, and may be disposed in the space between the first electronic component 11 and the lower substrate 2 so as to cover and protect the joints formed by the electrical contacts 114, the inner pads 242 and the solder materials 115. In some embodiments, the underfill 12 may be omitted. In some embodiments, the first electronic component 11 may have a second thickness T₂. For example, the second thickness T₂ may be about 320 μm to 350 μm. The second thickness T₂ of the first electronic component 11 may be greater than 2 times, 2.5 times, 3 times, or 3.5 times the first thickness T₁ of th lower substrate 2.

The at least one interconnection element 4 may include a plurality of interconnection elements 4 disposed around the first electronic component 11. The interconnection elements 4 may be disposed in the encapsulant 13. Each of the interconnection elements 4 may be a conductive wire or a bonding wire. In some embodiments, the interconnection elements 4 may physically connect, electrically connect and/or thermally connect the upper substrate 3 and the lower substrate 2, and may be configured to conductive heat and/or transmit signals. Thus, the interconnection elements 4 may have the function of transmitting signals (e.g., digital signals). The interconnection elements 4 may be configured to transfer heat between the upper substrate 3 and the lower substrate 2.

In some embodiments, the interconnection elements 4 may be electrically connected to and physically connected to the outer pads 241 of the lower substrate 2 through wire bonding process. The interconnection elements 4 may be nanowires. A material of the interconnection element 4 may include copper (Cu), gold (Au), aluminum (Al), or other suitable metal material. The interconnection element 4 may include a main portion 42 and a connecting portion 41. The connecting portion 41 may be in a substantially circular plate shape, and may directly contact the outer pad 241 of the lower substrate 2. A width of the connecting portion 41 may be greater than a width of the main portion 42. The width of the main portion 42 of the interconnection element 4 may be less than 100 nm, less than 80 nm, less than 50 nm, or less than 40 nm. The pitch of the interconnection elements 4 may be less than 250 nm, less than 200 nm, less than 150 nm, or less than 120 nm.

The main portion 42 and the connecting portion 41 may be formed integrally as a monolithic structure. The main portion 42 of the interconnection element 4 may have a substantially consistent width, and may be bent. That is, in a cross-sectional view, the main portion 42 of the interconnection element 4 may have a first section and a second section intersected with each other by an intersection angle greater than 90 degrees. Both of the first section and the second section may be substantially straight. The entire lateral surface of the main portion 42 of the interconnection element 4 may be not flat or linear in the cross-sectional view. In some embodiments, all the interconnection elements 4 may be bent toward a same direction.

The encapsulant 13 may be disposed over the lower substrate 2. The encapsulant 13 may be disposed between the upper substrate 3 and the lower substrate 2 to encapsulate the first electronic component 11, the underfill 12 and the interconnection elements 4. A material of the encapsulant 13 may be a molding compound with or without fillers. The encapsulant 13 may have a bottom surface 131 (e.g., a first surface), a top surface 132 (e.g., a second surface) opposite to the bottom surface 131, and a lateral surface extending between the top surface 132 and the bottom surface 131. The bottom surface 131 of the encapsulant 13 may contact the second surface 22 (e.g., the top surface) of the lower substrate 2. The top surface 112 (e.g., the backside surface) of the first electronic component 11 may be substantially aligned with or coplanar with the top surface 132 of the encapsulant 13. Thus, the top surface 112 (e.g., the backside surface) of the first electronic component 11 may be exposed by the encapsulant 13.

As shown in FIG. 2, the main portion 42 of the interconnection element 4 may have a top surface 421 and a lateral surface 423. The top surface 421 of the main portion 42 of the interconnection element 4 may be not level with or aligned with the top surface 132 of the encapsulant 13. In some embodiments, the top surface 421 of the main portion 42 of the interconnection element 4 may be lower than the top surface 132 of the encapsulant 13, so as to define a recess portion 134. The top surface 421 of the main portion 42 of the interconnection element 4 may be substantially parallel with the top surface 132 of the encapsulant 13. The lateral surface 423 of the main portion 42 of the interconnection element 4 may be not perpendicular to the top surface 132 of the encapsulant 13. The lateral surface 423 of the main portion 42 of the interconnection element 4 may be not perpendicular to the top surface 421 of the main portion 42 of the interconnection element 4. A surface roughness of the lateral surface 423 of the main portion 42 of the interconnection element 4 may be less than a surface roughness of the top surface 421 of the main portion 42 of the interconnection element 4.

The first metal material 51 and the second metal material 52 may be collectively formed a cap structure or an intermediate structure. The first metal material 51 may be disposed on the top surface 421 of the main portion 42 of the interconnection element 4, and may extend beyond the top surface 132 of the encapsulant 13. The first metal material 51 may be disposed on an upper portion of the interconnection element 4. Thus, the first metal material 51 may extend from the top surface 421 of the main portion 42 of the interconnection element 4 to over the top surface 132 of the encapsulant 13. The top surface 132 of the encapsulant 13 may horizontally overlap the first metal material 51.

The first metal material 51 may include an upper portion 512 and a lower portion 511. The lower portion 511 may be disposed in the recess portion 134, and may be lower than the top surface 132 of the encapsulant 13. The lower portion 511 may have a substantially consistent thickness and width. The upper portion 512 may be disposed on the lower portion 511, and may be higher than the top surface 132 of the encapsulant 13. A maximum width W₁ of the upper portion 512 of the first metal material 51 may be greater than a maximum width W₂ of the lower portion 511 of the first metal material 51. The maximum width W₂ of the lower portion 511 of the first metal material 51 may be substantially equal to a width W₂ of the main portion 42 of the interconnection element 4. The upper portion 512 of the first metal material 51 may taper away from the top surface 132 of the encapsulant 13 or may taper away from the lower substrate 2.

The upper portion 512 of the first metal material 51 may include a central portion 5121 and a periphery portion 5122 surrounding the central portion 5121. The central portion 5121 may have a substantially consistent thickness and may have a substantially flat top surface 5123. The periphery portion 5122 may taper away from the central portion 5121. The periphery portion 5122 may contact the top surface 132 of the encapsulant 13. In addition, a width W₃ of the substantially flat top surface 5123 of the central portion 5121 of the upper portion 512 of the first metal material 51 may be substantially equal to the width W₂ of the main portion 42 of the interconnection element 4.

The upper portion 512 and the lower portion 511 may be formed integrally as a monolithic structure. Thus, the first metal material 51 may be substantially in a mushroom shape, or a “T” shape. There may be no interface between the upper portion 512 and the lower portion 511. The first metal material 51 may include nickel (Ni), and may be formed by a deposition process, such as an electroless nickel immersion gold (ENIG) process, or an electroless nickel/electroless palladium/immersion gold (ENEPIG) process. In addition, a surface roughness of the substantially flat top surface 5123 of the central portion 5121 of the upper portion 512 of the first metal material 51 may be less than a surface roughness of the top surface 421 of the main portion 42 of the interconnection element 4.

The second metal material 52 may be conformally formed or disposed on the first metal material 51. The second metal material 52 may be a metal layer that has a substantially consistent thickness. The second metal material 52 may be formed or disposed on the entire top surface of the first metal material 51, and may contact the top surface 132 of the encapsulant 13. A thickness of the second metal material 52 may be less than a thickness of the central portion 5121 of the upper portion 512 of the first metal material 51 or a thickness of the lower portion 511 of the first metal material 51. The second metal material 52 may include gold (Au), and may be formed by a deposition process, such as an electroless nickel immersion gold (ENIG) process, or an electroless nickel/electroless palladium/immersion gold (ENEPIG) process.

As shown in FIG. 1, the heat dissipation structure 14 may be formed or disposed on the top surface 112 (e.g., the backside surface) of the first electronic component 11. Thus, the heat dissipation structure 14 may directly contact the top surface 112 (e.g., the backside surface) of the first electronic component 11. In some embodiments, the heat dissipation structure 14 may extend to the top surface 132 of the encapsulant 13. Thus, the heat dissipation structure 14 may directly contact the top surface 132 of the encapsulant 13. As shown in FIG. 1, the heat dissipation structure 14 may be disposed between the upper the upper substrate 3 and the first electronic component 11. Thus, the heat dissipation structure 14 may physically connect, electrically connect and/or thermally connect the upper substrate 3 and the first electronic component 11, and may be configured to conductive heat and/or transmit signals. Thus, the heat dissipation structure 14 may or may not have the function of transmitting signals (e.g., digital signals). The heat dissipation structure 14 may be configured to transfer heat between the first electronic component 11 and the upper substrate 3. For example, the heat dissipation structure 14 may be configured to dissipate heat from the first electronic component 11 to the upper substrate 3. In some embodiments, the heat dissipation structure 14 may include a thermal conductive film, such as a die attach film (DAF), a thermal interface material (TIM), a thermal conductive adhesive or a metal heat sink. Alternatively, the heat dissipation structure 14 may include a plurality of wires.

The upper substrate 3 (e.g., a thermal conductive structure) may be disposed over the lower substrate 2 and the first electronic component 11. There may be a gap between the first electronic component 11 and the upper substrate 3. The upper substrate 3 may be physically connected and electrically connected to the lower substrate 2 through the interconnection element(s) 4 and the at least one solder material 15. The upper substrate 3 may be a second substrate, a circuit pattern structure, a redistribution layer (RDL) structure, a wiring structure or a substrate structure, and may be disposed on a top surface of the heat dissipation structure 14. The upper substrate 3 may have a first surface 31 (e.g., a bottom surface) and a second surface 32 (e.g., a top surface) opposite to the first surface 31. The upper substrate 3 may include at least one dielectric layer 33, at least one circuit layer 34 (e.g., a patterned circuit layer or a redistribution layer) and at least one inner via 35.

As shown in FIG. 1, the upper substrate 3 may include three dielectric layers 33, three circuit layers 34 and a plurality of inner vias 35. However, the amount of the dielectric layers 33 and the amount of the circuit layers 34 are not limited in the present disclosure. The dielectric layer 33 may be made of a cured photoimageable dielectric (PID) material such as epoxy or polyimide (PI) including photoinitiators. The dielectric layers 33 may cover the circuit layers 34, and may be stacked on one another. The inner vias 35 may connect the circuit layers 34. The inner via 35 may taper upward. Thus, a width of the inner via 35 may decrease upward. The circuit layer 34 may include a seed layer and a conductive layer disposed on the seed layer. In some embodiments, the seed layer may be omitted.

A bottommost one of the circuit layers 34 may include at least one outer bond pad 341 and at least one first inner thermal pad 342 exposed from a bottommost one of the dielectric layers 33. A bottom surface of the outer bond pad 341 and a bottom surface of the first inner thermal pad 342 may be substantially coplanar with or aligned with a bottom surface of the bottommost dielectric layer 33 (i.e., the first surface 31 (the bottom surface) of the upper substrate 3). A middle one of the circuit layers 34 may include at least one second inner thermal pad 343. In addition, the topmost circuit layer 34 may include at least one top pad 345 and at least one third inner thermal pad 344 exposed by a topmost one of the dielectric layers 33. A top surface of the top pad 345 and a top surface of the third inner thermal pad 344 may be substantially coplanar with or aligned with a top surface of the topmost dielectric layer 33 (i.e., the second surface 32 (the top surface) of the upper substrate 3).

The first inner thermal pad 342, the second inner thermal pad 343 and the third inner thermal pad 344 may have a large area, and may physically connect, electrically connect and/or thermally connect one and another through the inner vias 35. The first inner thermal pad 342 may contact the top surface of the heat dissipation structure 14. Thus, the first surface 31 (the bottom surface) of the upper substrate 3 may directly contact the heat dissipation structure 14. A width of the first inner thermal pad 342, a width of the second inner thermal pad 343, a width of the third inner thermal pad 344, a width of the heat dissipation structure 14 and a width of the first electronic component 11 may be substantially equal to or different from each other. In some embodiments, the upper substrate 3 may have a third thickness T₃. For example, the third thickness T₃ may be about 60 μm to 80 μm. The third thickness T₃ of the upper substrate 3 may be less than the first thickness T₁ of the lower substrate 2. The second thickness T₂ of the first electronic component 11 may be greater than a sum of the first thickness T₁ of the lower substrate 2 and the third thickness T₃ of the upper substrate 3.

In some embodiments, the upper substrate 3 may be also referred to as “a stacked structure” or “a high-density electronic structure” or “a high-density stacked structure.” The circuit layers 34 of the upper substrate 3 may be also referred to as “a high-density redistribution layer.” The lower substrate 2 may be also referred to as “a stacked structure” or “a low-density electronic structure” or “a low-density stacked structure.” The circuit layers 24 of the lower substrate 2 may be also referred to as “a low-density redistribution layer.” However, in some embodiments, the upper substrate 3 may be also referred to as “a low-density electronic structure” or “a low-density stacked structure.” The circuit layer 34 of the upper substrate 3 may be also referred to as “a low-density redistribution layer.” The lower substrate 2 may be also referred to as “a high-density electronic structure” or “a high-density stacked structure.” The circuit layer 24 of the lower substrate 2 may be also referred to as “a high-density redistribution layer.” It is noted that a density of a circuit line (including, for example, a trace or a pad) of the high-density redistribution layer is greater than a density of a circuit line of a low-density redistribution layer. That is, the count of the circuit line (including, for example, a trace or a pad) in a unit area of the high-density redistribution layer is greater than the count of the circuit line in an equal unit area of the low-density redistribution layer, such as about 1.2 times or greater, about 1.5 times or greater, or about 2 times or greater, or about 5 times or greater. Alternatively, or in combination, a line width/line space (L/S) of the high-density redistribution layer is less than an L/S of the low-density redistribution layer, such as about 90% or less, about 50% or less, or about 20% or less.

The at least one solder material 15 may include a plurality of solder materials 15. The solder material 15 may include a re-flowable material such as SnAg alloy. The solder material 15 may electrically connect and physically connect the outer bond pad 341 of the upper substrate 3 and the second metal material 52. The solder material 15 may be disposed on the second metal material 52 and may cover and contact the entire top surface of the second metal material 52. The solder material 15 may or may not contact the top surface 132 of the encapsulant 13. A lateral surface of the solder material 15 may include a curved surface.

The protection material 16 (e.g., an underfill) may be disposed in the gap between the top surface 132 of the encapsulant 13 and the first surface 31 (the bottom surface) of the upper substrate 3 so as to cover and contact the solder materials 15.

The second electronic component 17 may be disposed over the upper substrate 3. The second electronic component 17 may be electrically connected and physically connected to the top pad 345 of the upper substrate 3 through the at least one connecting element 18. The connecting element 18 may include a solder material or a re-flowable material such as SnAg alloy. The second electronic component 17 may be a semiconductor device such as an application specific integrated circuit (ASIC) die or a high bandwidth memory (HBM) die. The function of the second electronic component 17 may be different from the function of the first electronic component 11. A thickness of the second electronic component 17 may be less than the second thickness T₂ of the first electronic component 11.

The at least one external connector 19 may include a plurality of external connectors 19 for external connection. The external connector 19 may include a re-flowable material such as SnAg alloy. The external connector 19 may be formed or disposed on the bottom pad 243 of the bottommost circuit layer 24 of the lower substrate 2 exposed by a bottom surface of the bottommost dielectric layer 23 (i.e., the first surface 21 (the bottom surface) of the lower substrate 2).

In the embodiment illustrated in FIG. 1 and FIG. 2, the second thickness T₂ of the first electronic component 11 may be greater than a sum of the first thickness T₁ of the lower substrate 2 and the third thickness T₃ of the upper substrate 3, thus, there may be a relatively long distance or greater gap between the lower substrate 2 and the upper substrate 3, which will increase the difficulty of manufacturing the electronic package structure 1. A metal wire can achieve a long distance connection, thus, when the interconnection element 4 is a metal wire, the difficulty of manufacturing the electronic package structure 1 may be improved.

Further, the heat generated by the first electronic component 11 will be dissipated to the second surface 32 (the top surface) of the upper substrate 3 efficiently through the heat dissipation structure 14, the first inner thermal pad 342, the second inner thermal pad 343 and the third inner thermal pad 344. As a result, a heat dissipation efficiency of the electronic package structure 1 may be improved.

In addition, the solder material 15 may be electrically connected to the interconnection element 4 through the first metal material 51 and the second metal material 52. Since the maximum width W₁ of the upper portion 512 of the first metal material 51 may be greater than the width W₂ of the main portion 42 of the interconnection element 4, the contact area between the solder material 15 and the second metal material 52 may be enlarged. Thus, the reliability of the bonding between the solder material 15 and the second metal material 52 may be improved. In addition, the second metal material 52, exemplified by gold, can enhance the bonding between the solder material 15 and the first metal material 51, exemplified by nickel.

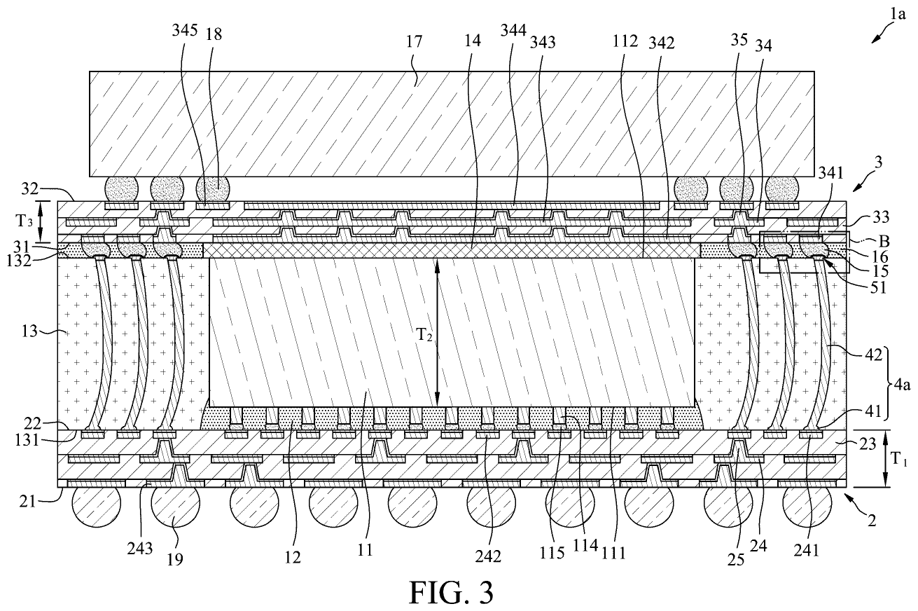

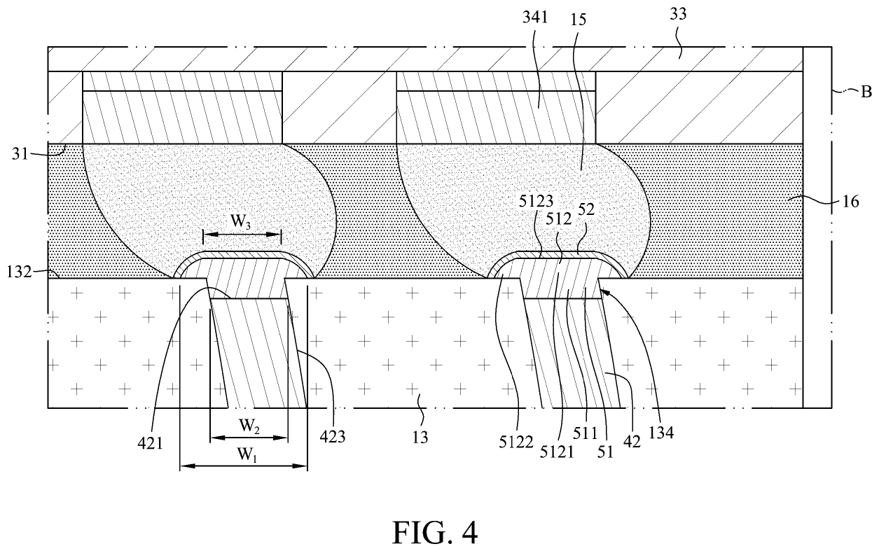

FIG. 3 illustrates a cross-sectional view of an electronic package structure 1a according to some embodiments of the present disclosure. FIG. 4 illustrates an enlarged view of an area “B” of FIG. 3. The electronic package structure 1a of FIG. 3 and FIG. 4 is similar to the electronic package structure 1 of FIG. 1 and FIG. 2, and the differences are described as follows. In a cross-sectional view of the electronic package structure 1a, the main portion 42 of the interconnection element 4a may have a warpage or a curved profile. The entire lateral surface of the main portion 42 of the interconnection element 4a may be not flat or linear in the cross-sectional view. In some embodiments, all the interconnection elements 4a may be curved toward a same direction. In addition, a center of the outer bond pad 341 may be misaligned with or shift with a center of a top surface 421 of the interconnection element 4a in a direction perpendicular to the top surface 132 of the encapsulant 13. In addition, the first metal material 51 and the second metal material 52 may be misaligned with the solder material 15. Due to the material and the structure of the first metal material 51 and the second metal material 52, the solder material 15 may be disposed on the second metal material 52 and may connect to the outer bond pad 341. Thus, the bonding between the second metal material 52 and the solder material 15 and the outer bond pad 341 may be still secured.

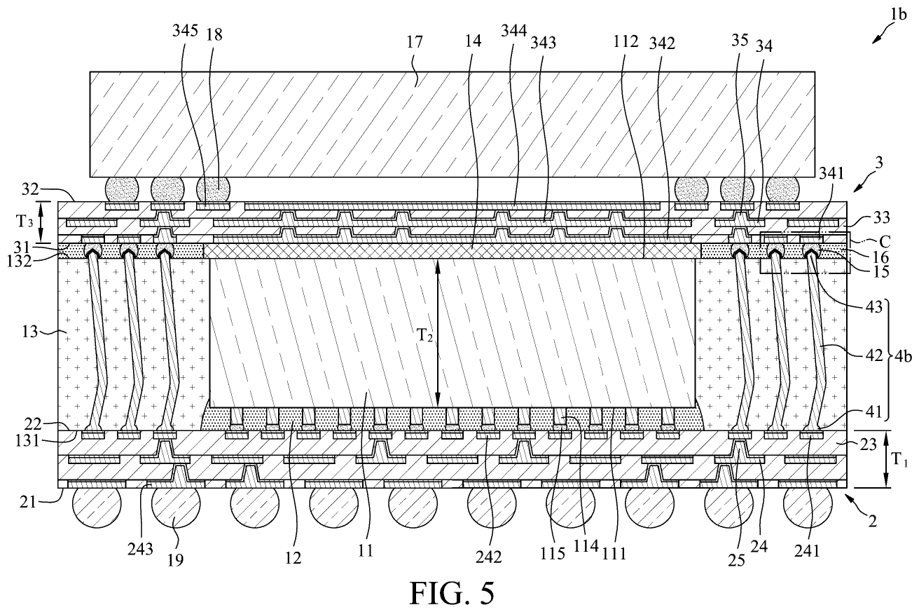

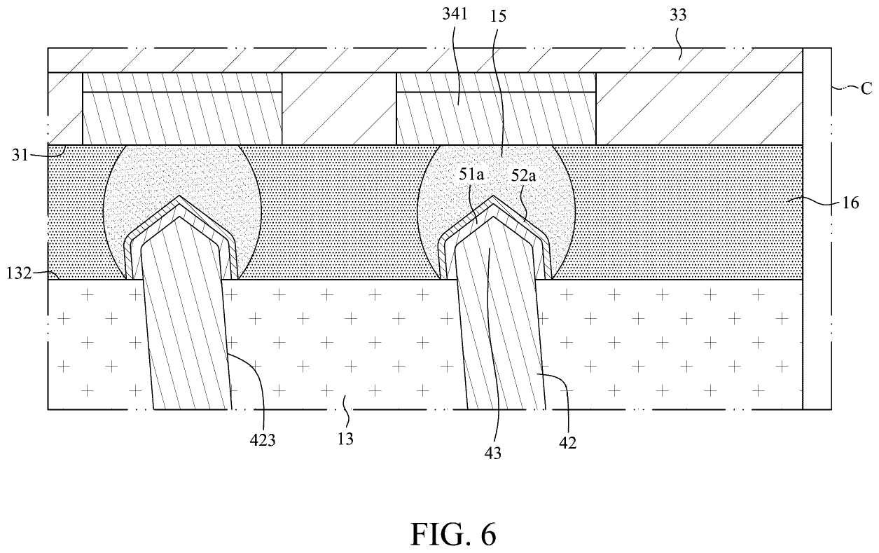

FIG. 5 illustrates a cross-sectional view of an electronic package structure 1b according to some embodiments of the present disclosure. FIG. 6 illustrates an enlarged view of an area “C” of FIG. 5. The electronic package structure 1b of FIG. 5 and FIG. 6 is similar to the electronic package structure 1 of FIG. 1 and FIG. 2, and the differences are described as follows. The interconnection element 4b of the electronic package structure 1b may be electrically connected to and physically connected to the outer pad 241 of the lower substrate 2 through wire bonding process. The interconnection elements 4b may be nanowires. A material of the interconnection element 4b may include copper (Cu), gold (Au), aluminum (Al), or other suitable metal material. The interconnection element 4b may include a main portion 42, a connecting portion 41 and an upper portion 43. The connecting portion 41 may be in a substantially circular plate shape, and may directly contact the outer pad 241 of the lower substrate 2. A width of the connecting portion 41 may be greater than a width of the main portion 42.

The main portion 42, the connecting portion 41 and the upper portion 43 may be formed integrally as a monolithic structure. The main portion 42 of the interconnection element 4b may have a substantially consistent width, and may be bent. That is, in a cross-sectional view, the main portion 42 of the interconnection element 4b may have a first section and a second section intersected with each other by an intersection angle greater than 90 degrees. The entire lateral surface of the main portion 42 of the interconnection element 4b may be not flat or linear in the cross-sectional view. The main portion 42 and the connecting portion 41 of the interconnection element 4b may be disposed in the encapsulant 13. The main portion 42 of the interconnection element 4b may have a warpage or a curved profile. The upper portion 43 of the interconnection element 4b may extend beyond the top surface 132 of the encapsulant 13. Thus, the top surface 132 of the encapsulant 13 may horizontally overlap the interconnection element 4b. In addition, the upper portion 43 of the interconnection element 4b may taper away from the top surface 132 of the encapsulant 13 or may taper away from the lower substrate 2.

The first metal material 51a may be conformally disposed on the upper portion 43 of the interconnection element 4b. The second metal material 52a may be conformally disposed on the first metal material 51a. The first metal material 51a may have a substantially consistent thickness. The second metal material 52a may have a substantially consistent thickness. The thickness of the first metal material 51a may be greater than the thickness of the second metal material 52a. Both of the first metal material 51a and the second metal material 52a may contact the top surface 132 of the encapsulant 13.

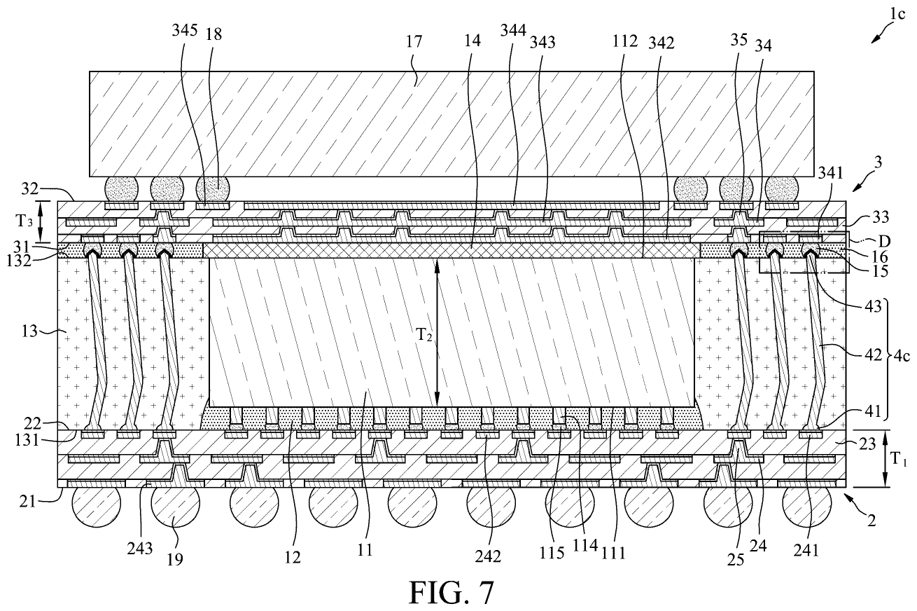

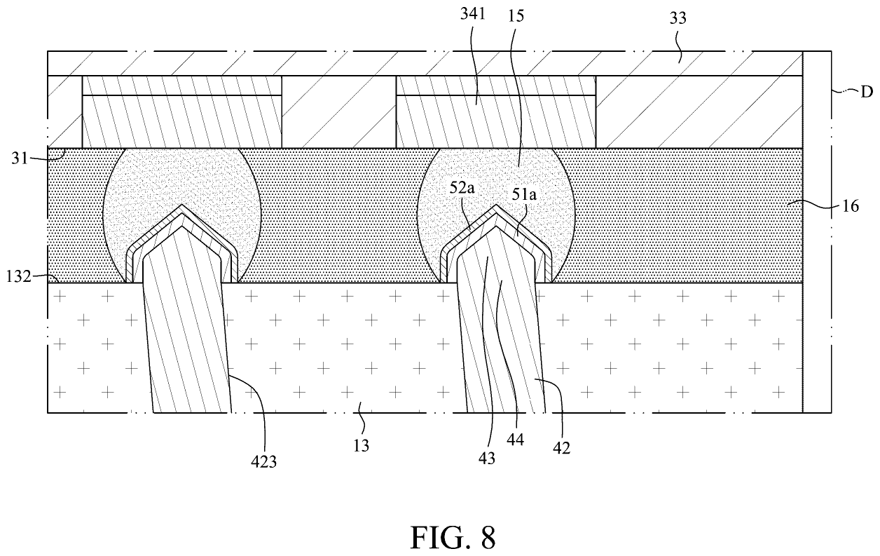

FIG. 7 illustrates a cross-sectional view of an electronic package structure 1c according to some embodiments of the present disclosure. FIG. 8 illustrates an enlarged view of an area “D” of FIG. 7. The electronic package structure 1c of FIG. 7 and FIG. 8 is similar to the electronic package structure 1b of FIG. 5 and FIG. 6, and the differences are described as follows. The interconnection element 4c of the electronic package structure 1c may have a turning point 44 formed between the upper portion 43 of the interconnection element 4c and the main portion 42 of the interconnection element 4c. An extending direction of the upper portion 43 of the interconnection element 4c may be different from an extending direction of the main portion 42 of the interconnection element 4c. The upper portion 43 of the interconnection element 4c and the main portion 42 of the interconnection element 4c may intersect with each other by an intersection angle greater than 90 degrees.

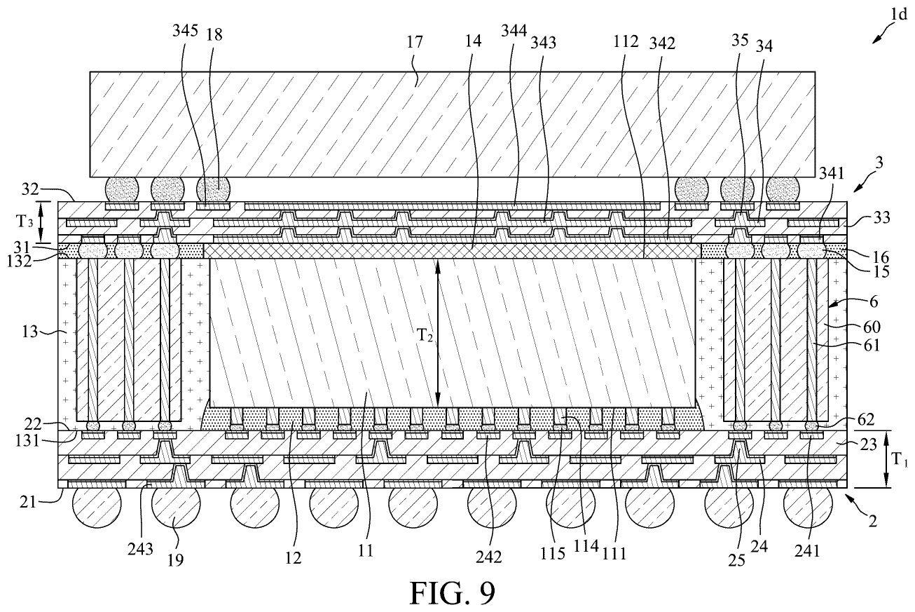

FIG. 9 illustrates a cross-sectional view of an electronic package structure 1d according to some embodiments of the present disclosure. The electronic package structure 1d of FIG. 9 is similar to the electronic package structure 1 of FIG. 1 and FIG. 2, and the differences are described as follows. The interconnection element 4 of FIG. 1 and FIG. 2 may be replaced by an interposer 6 of FIG. 9. The interposer 6 may include a main portion 60 and at least one through via 61. The main portion 60 may include silicon (Si), glass or dielectric material. The through via 61 may include metal material, and may extend through the main portion 60. A top surface of the main portion 60 may be substantially aligned with or coplanar with the top surface 112 (e.g., the backside surface) of the first electronic component 11 and the top surface 132 of the encapsulant 13. The solder material 15 may be electrically connected to and physically connected to a top end of the through via 61. A bottom end of the through via 61 may be electrically connected to and physically connected to the outer pad 241 of the lower substrate 2 through a solder material 62.

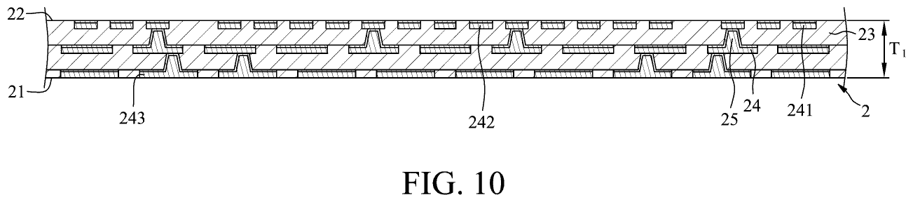

FIG. 10 through FIG. 21 illustrate a method for manufacturing an electronic package structure according to some embodiments of the present disclosure. In some embodiments, the method is for manufacturing the electronic package structure 1 shown in FIG. 1 and FIG. 2.

Referring to FIG. 10, a lower substrate 2 may be provided. The lower substrate 2 of FIG. 10 may be the same as the lower substrate 2 of FIG. 1.

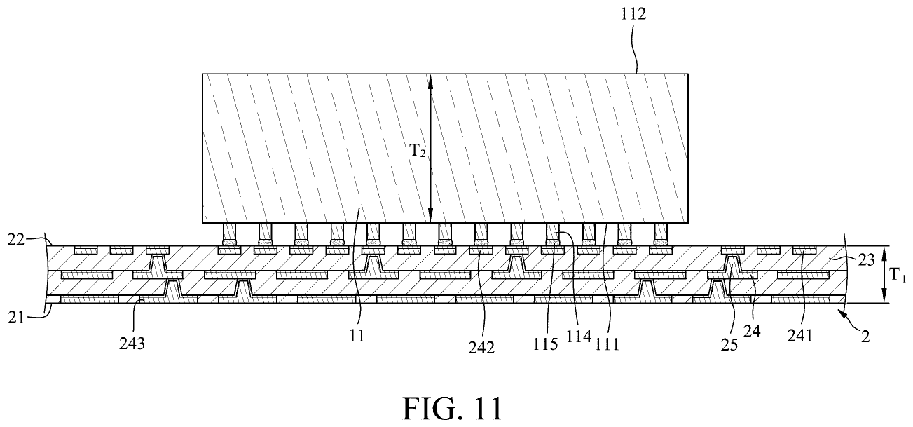

Referring to FIG. 11, a first electronic component 11 may be attached to or bonded to the lower substrate 2, and electrically connected to the circuit layer 24 of the lower substrate 2. The first electronic component 11 may have a bottom surface 111 (e.g., an active surface), a top surface 112 (e.g., a backside surface) opposite to the bottom surface 111, and a lateral surface extending between the top surface 112 and the bottom surface 111. The first electronic component 11 may include a plurality of electrical contacts 114. The electrical contacts 114 may be disposed adjacent to the bottom surface 111 (e.g., the active surface) of the first electronic component 11. The electrical contacts 114 may be exposed or may protrude from the bottom surface 111 (e.g., the active surface) for electrical connection. In some embodiments, the electrical contacts 114 of the first electronic component 11 may be electrically connected to and physically connected to the inner pads 242 of the lower substrate 2 through a plurality of solder materials 115. In other words, the first electronic component 11 may be electrically connected to the lower substrate 2 by flip-chip bonding.

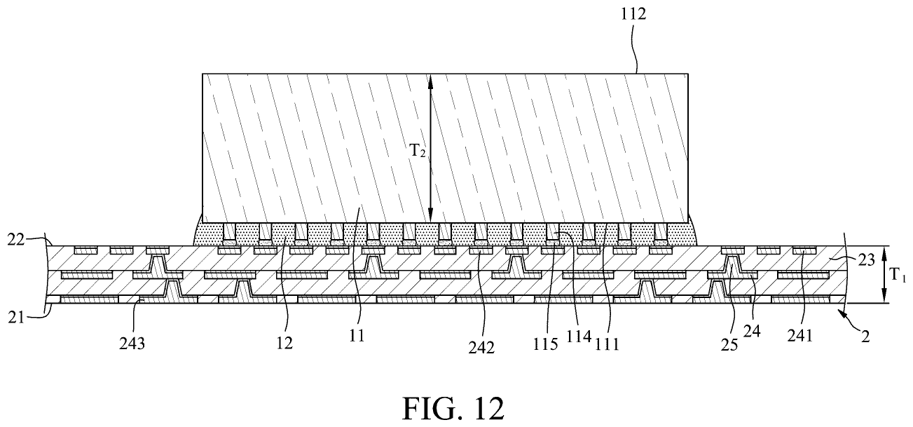

Referring to FIG. 12, an underfill 12 may be formed or disposed in the space between the first electronic component 11 and the lower substrate 2 so as to cover and protect the joints formed by the electrical contacts 114, the inner pads 242 and the solder materials 115.

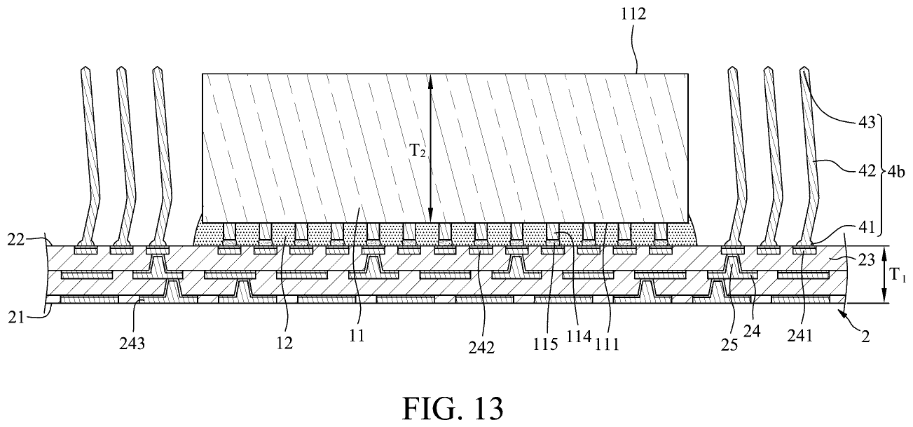

Referring to FIG. 13, at least one interconnection element 4b may be formed or disposed on the lower substrate 2. The at least one interconnection element 4b may include a plurality of interconnection elements 4b disposed around the first electronic component 11. Each of the interconnection elements 4b may be a conductive wire or a bonding wire. In some embodiments, the interconnection elements 4b may be electrically connected to and physically connected to the outer pads 241 of the lower substrate 2 through wire bonding process. The interconnection elements 4b may be nanowires. The interconnection element 4b may include a main portion 42 and a connecting portion 41 and an upper portion 43. The connecting portion 41 may be in a substantially circular plate shape, and may directly contact the outer pad 241 of the lower substrate 2. A width of the connecting portion 41 may be greater than a width of the main portion 42.

The main portion 42, the connecting portion 41 and the upper portion 43 may be formed integrally as a monolithic structure. The main portion 42 of the interconnection element 4 may have a substantially consistent width, and may be bent. That is, in a cross-sectional view, the main portion 42 of the interconnection element 4 may have a first section and a second section intersected with each other by an intersection angle greater than 90 degrees. Both of the first section and the second section may be substantially straight. The entire lateral surface of the main portion 42 of the interconnection element 4 may be not flat or linear in the cross-sectional view. In some embodiments, all the interconnection elements 4 may be bent toward a same direction. The upper portion 43 of the interconnection element 4b may be higher than the top surface 112 (e.g., the backside surface) of the first electronic component 11.

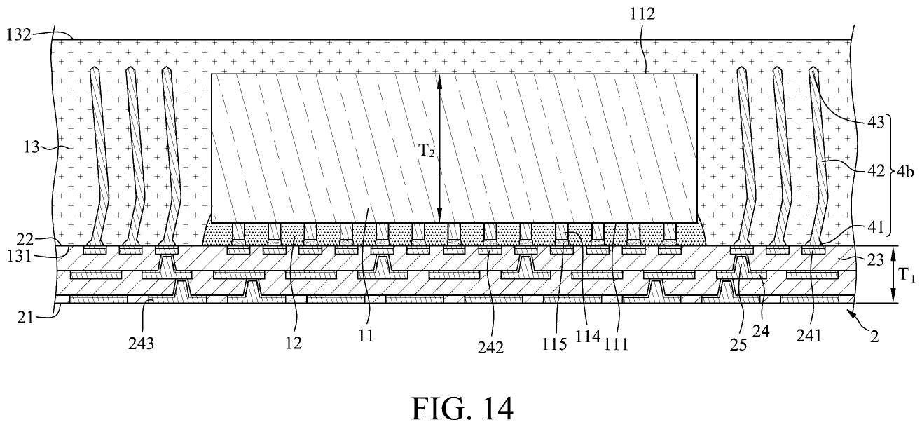

Referring to FIG. 14, an encapsulant 13 may be formed or disposed over the lower substrate 2. The encapsulant 13 may encapsulate the first electronic component 11, the underfill 12 and the interconnection elements 4b. The encapsulant 13 may have a bottom surface 131 (e.g., a first surface) and a top surface 132 (e.g., a second surface) opposite to the bottom surface 131. The bottom surface 131 of the encapsulant 13 may contact the second surface 22 (e.g., the top surface) of the lower substrate 2. The top surface 112 (e.g., the backside surface) of the first electronic component 11 may be lower than the top surface 132 of the encapsulant 13.

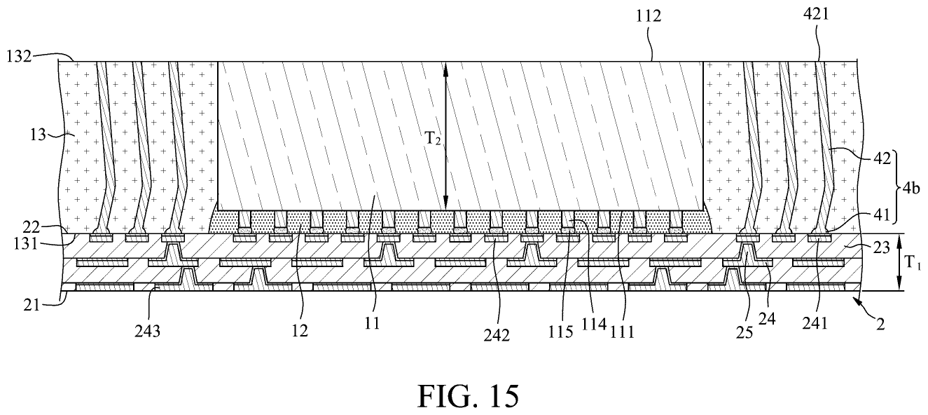

Referring to FIG. 15, a grinding process may be conducted so as to grind the top surface 132 of the encapsulant 13 to expose a top surface 112 (e.g., the backside surface) of the first electronic component 11 and the interconnection element 4b. The upper portion 43 of the interconnection element 4b and a portion of the encapsulant 13 may be removed. As shown in FIG. 15, the main portion 42 of the interconnection element 4 may have a top surface 421 and a lateral surface 423. The top surface 421 of the main portion 42 of the interconnection element 4 may be substantially coplanar with or aligned with the top surface 132 of the encapsulant 13. The lateral surface 423 of the main portion 42 of the interconnection element 4 may be not perpendicular to the top surface 132 of the encapsulant 13. The lateral surface 423 of the main portion 42 of the interconnection element 4 may be not perpendicular to the top surface 421 of the main portion 42 of the interconnection element 4.

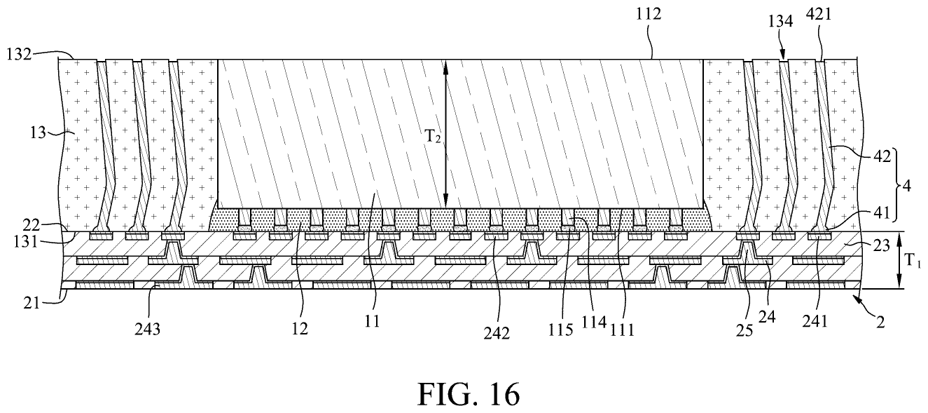

Referring to FIG. 16, a portion of the main portion 42 of the interconnection element 4b may be removed by, for example, etching process. Meanwhile, the interconnection element 4b may become an interconnection element 4. The top surface 421 of the main portion 42 of the interconnection element 4 may be lower than the top surface 132 of the encapsulant 13, so as to define a recess portion 134. The top surface 421 of the main portion 42 of the interconnection element 4 may be substantially parallel with the top surface 132 of the encapsulant 13. A surface roughness of the lateral surface 423 of the main portion 42 of the interconnection element 4 may be less than a surface roughness of the top surface 421 of the main portion 42 of the interconnection element 4.

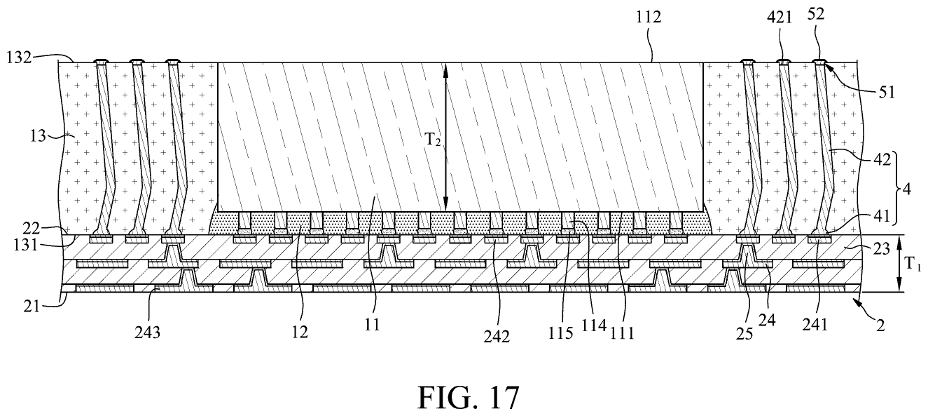

Referring to FIG. 17, a first metal material 51 may be formed or disposed on the top surface 421 of the main portion 42 of the interconnection element 4. The first metal material 51 may extend beyond the top surface 132 of the encapsulant 13. Thus, the first metal material 51 may extend from the top surface 421 of the main portion 42 of the interconnection element 4 to over the top surface 132 of the encapsulant 13. The top surface 132 of the encapsulant 13 may horizontally overlap the first metal material 51. The first metal material 51 may include an upper portion 512 and a lower portion 511. The lower portion 511 may be disposed in the recess portion 134, and may be lower than the top surface 132 of the encapsulant 13. The lower portion 511 may have a substantially consistent thickness and width. The upper portion 512 may be disposed on the lower portion 511, and may be higher than the top surface 132 of the encapsulant 13.

The upper portion 512 of the first metal material 51 may taper away from the lower substrate 2. The upper portion 512 of the first metal material 51 may include a central portion 5121 and a periphery portion 5122 surrounding the central portion 5121. The central portion 5121 may have a substantially consistent thickness and may have a substantially flat top surface 5123. The periphery portion 5122 may taper away from the central portion 5121. The periphery portion 5122 may contact the top surface 132 of the encapsulant 13.

The upper portion 512 and the lower portion 511 may be formed integrally as a monolithic structure. Thus, the first metal material 51 may be substantially in a mushroom shape, or a “T” shape. There may be no interface between the upper portion 512 and the lower portion 511. The first metal material 51 may include nickel (Ni), and may be formed by a deposition process, such as an electroless nickel immersion gold (ENIG) process, or an electroless nickel/electroless palladium/immersion gold (ENEPIG) process. In addition, a surface roughness of the substantially flat top surface 5123 of the central portion 5121 of the upper portion 512 of the first metal material 51 may be less than a surface roughness of the top surface 421 of the main portion 42 of the interconnection element 4.

Then, a second metal material 52 may be conformally formed or disposed on the first metal material 51. The second metal material 52 may be a metal layer that has a substantially consistent thickness. The second metal material 52 may be formed or disposed on the entire top surface of the first metal material 51, and may contact the top surface 132 of the encapsulant 13. A thickness of the second metal material 52 may be less than a thickness of the central portion 5121 of the upper portion 512 of the first metal material 51 or a thickness of the lower portion 511 of the first metal material 51. The second metal material 52 may include gold (Au), and may be formed by a deposition process, such as an electroless nickel immersion gold (ENIG) process, or an electroless nickel/electroless palladium/immersion gold (ENEPIG) process.

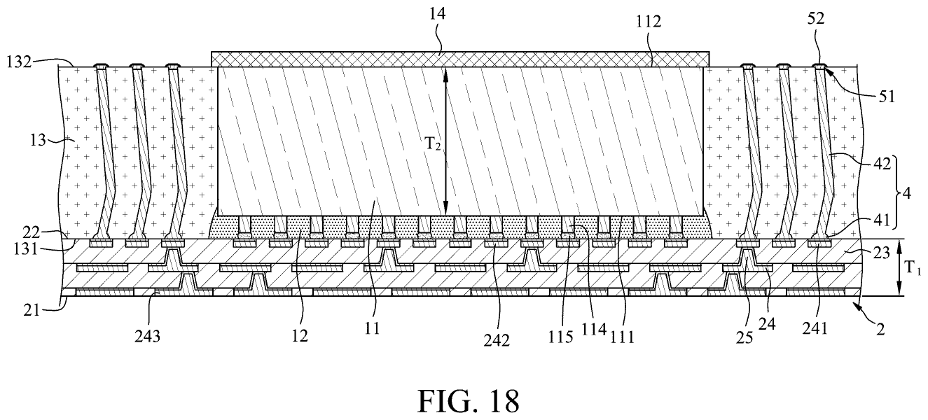

Referring to FIG. 18, a heat dissipation structure 14 may be formed or disposed on the top surface 112 (e.g., the backside surface) of the first electronic component 11. The heat dissipation structure 14 may directly contact the top surface 112 (e.g., the backside surface) of the first electronic component 11. In some embodiments, the heat dissipation structure 14 may extend to the top surface 132 of the encapsulant 13. Thus, the heat dissipation structure 14 may directly contact the top surface 132 of the encapsulant 13. The heat dissipation structure 14 may physically connect, electrically connect and/or thermally connect the first electronic component 11, and may be configured to conductive heat and/or transmit signals. In some embodiments, the heat dissipation structure 14 may include a thermal conductive film, such as a die attach film (DAF), a thermal interface material (TIM), a thermal conductive adhesive or a metal heat sink. Alternatively, the heat dissipation structure 14 may include a plurality of wires.

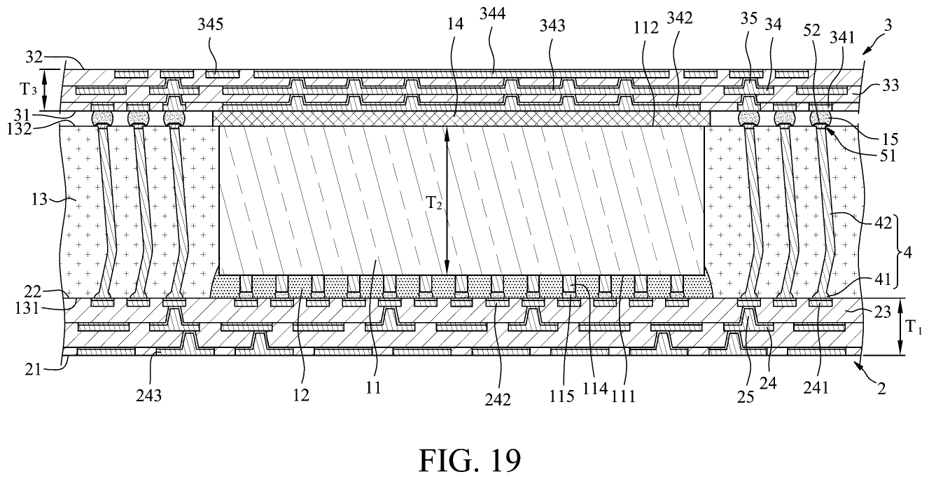

Referring to FIG. 19, an upper substrate 3 may be disposed over the lower substrate 2 and the first electronic component 11. The upper substrate 3 of FIG. 19 may be the same as the upper substrate 3 of FIG. 1. There may be a gap between the upper substrate 3 and the top surface 132 of the encapsulant 13. The upper substrate 3 may be physically connected and electrically connected to the lower substrate 2 through the interconnection element(s) 4 and at least one solder material 15. The solder material 15 may include a re-flowable material such as SnAg alloy. The solder material 15 may electrically connect and physically connect the outer bond pad 341 of the upper substrate 3 and the second metal material 52. The solder material 15 may cover and contact the entire top surface of the second metal material 52. The solder material 15 may or may not contact the top surface 132 of the encapsulant 13. A lateral surface of the solder material 15 may include a curved surface. Meanwhile, the first surface 31 (the bottom surface) of the upper substrate 3 may directly contact the heat dissipation structure 14.

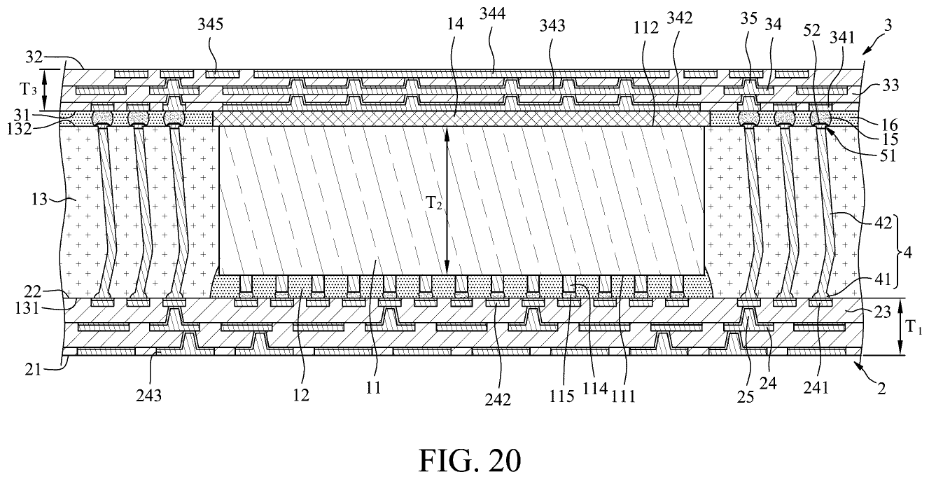

Referring to FIG. 20, a protection material 16 (e.g., an underfill) may be formed or disposed in the gap between the top surface 132 of the encapsulant 13 and the first surface 31 (the bottom surface) of the upper substrate 3 so as to cover and contact the solder materials 15.

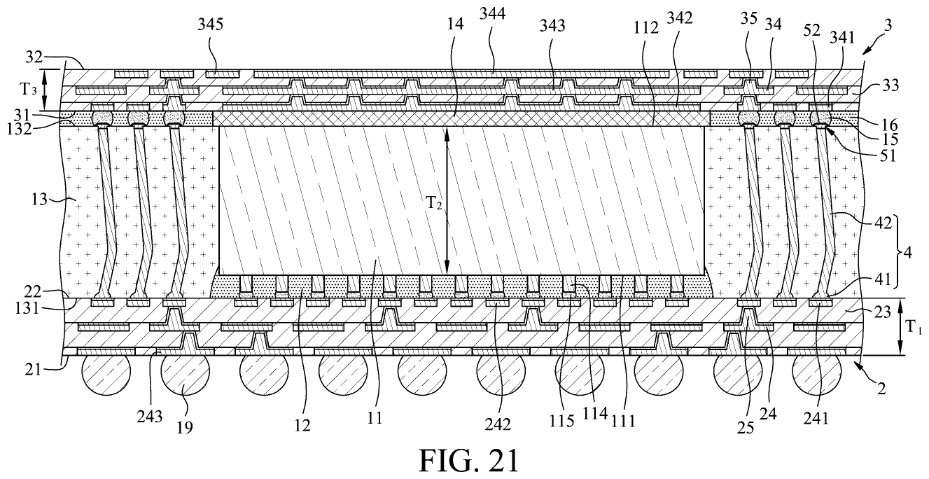

Referring to FIG. 21, at least one external connector 19 may be formed or disposed on the bottom pad 243 of the bottommost circuit layer 24 of the lower substrate 2 that is exposed by a bottom surface of the bottommost dielectric layer 23 (i.e., the first surface 21 (the bottom surface) of the lower substrate 2). The at least one external connector 19 may include a plurality of external connectors 19 for external connection. The external connector 19 may include a re-flowable material such as SnAg alloy.

Then, a second electronic component 17 may be disposed over the upper substrate 3. The second electronic component 17 may be electrically connected and physically connected to the top pad 345 of the upper substrate 3 through at least one connecting element 18. The connecting element 18 may include a solder material or a re-flowable material such as SnAg alloy. The function of the second electronic component 17 may be different from the function of the first electronic component 11.

Then, a singulation process may be conducted to obtain a plurality of electronic package structures 1 of FIG. 1 and FIG. 2.

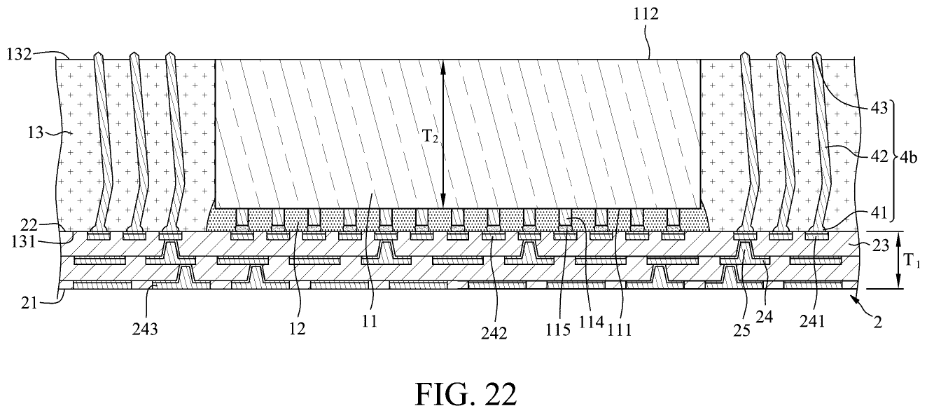

FIG. 22 through FIG. 29 illustrate a method for manufacturing an electronic package structure according to some embodiments of the present disclosure. In some embodiments, the method is for manufacturing the electronic package structure 1b shown in FIG. 5 and FIG. 6. The initial stages of the illustrated process are the same as, or similar to, the stages illustrated in FIG. 10 to FIG. 13. FIG. 22 depicts a stage subsequent to that depicted in FIG. 13.

Referring to FIG. 22, an encapsulant 13 may be formed or disposed over the lower substrate 2. The encapsulant 13 may encapsulate the first electronic component 11, the underfill 12 and the interconnection elements 4b. The encapsulant 13 may have a bottom surface 131 (e.g., a first surface) and a top surface 132 (e.g., a second surface) opposite to the bottom surface 131. The bottom surface 131 of the encapsulant 13 may contact the second surface 22 (e.g., the top surface) of the lower substrate 2. The main portion 42 and the connecting portion 41 of the interconnection element 4b may be disposed in the encapsulant 13. The upper portion 43 of the interconnection element 4b may extend beyond the top surface 132 of the encapsulant 13. Thus, the top surface 132 of the encapsulant 13 may horizontally overlap the interconnection element 4b. In addition, the upper portion 43 of the interconnection element 4b may taper away from the lower substrate 2. The top surface 112 (e.g., the backside surface) of the first electronic component 11 may be substantially coplanar with or aligned with the top surface 132 of the encapsulant 13.

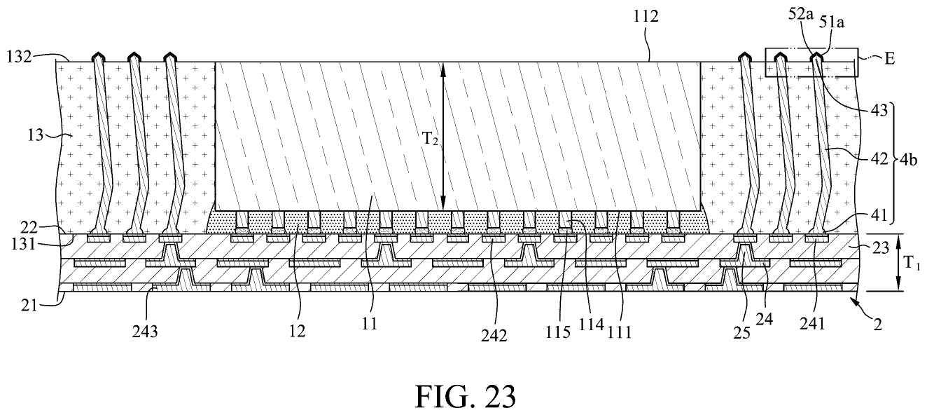

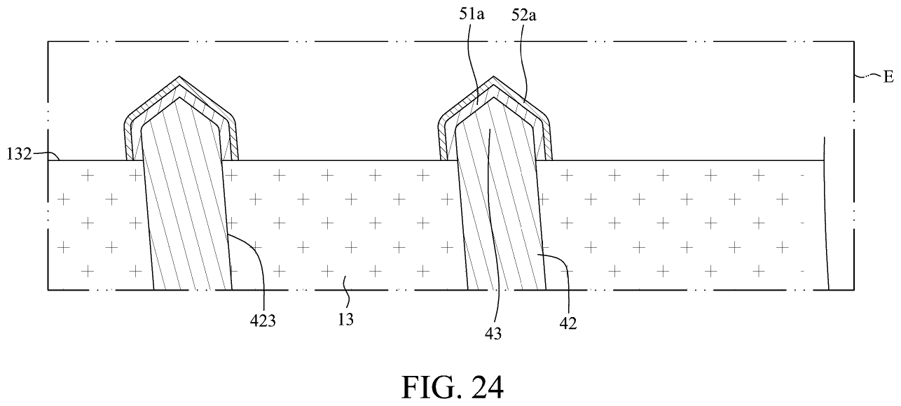

Referring to FIG. 23 and FIG. 24, wherein FIG. 24 illustrates an enlarged view of an area “E” of FIG. 23, a first metal material 51a may be conformally formed or disposed on the upper portion 43 of the interconnection element 4b. Then, the second metal material 52a may be conformally formed or disposed on the first metal material 51a. The first metal material 51a may have a substantially consistent thickness. The second metal material 52a may have a substantially consistent thickness. The thickness of the first metal material 51a may be greater than the thickness of the second metal material 52a. Both of the first metal material 51a and the second metal material 52a may contact the top surface 132 of the encapsulant 13.

Thus, the first metal material 51a and the second metal material 52a may be substantially in a triangle shape. The first metal material 51a may include nickel (Ni), and may be formed by a deposition process, such as an electroless nickel immersion gold (ENIG) process, or an electroless nickel/electroless palladium/immersion gold (ENEPIG) process. The second metal material 52a may include gold (Au), and may be formed by a deposition process, such as an electroless nickel immersion gold (ENIG) process, or an electroless nickel/electroless palladium/immersion gold (ENEPIG) process.

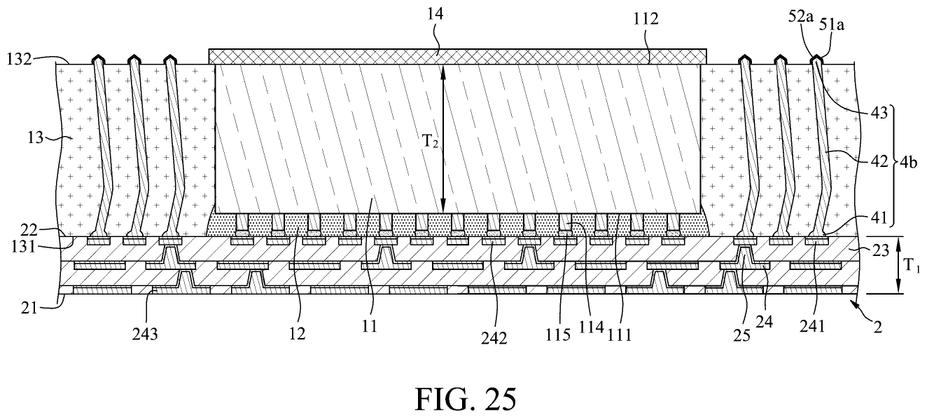

Referring to FIG. 25, a heat dissipation structure 14 may be formed or disposed on the top surface 112 (e.g., the backside surface) of the first electronic component 11. The heat dissipation structure 14 may directly contact the top surface 112 (e.g., the backside surface) of the first electronic component 11.

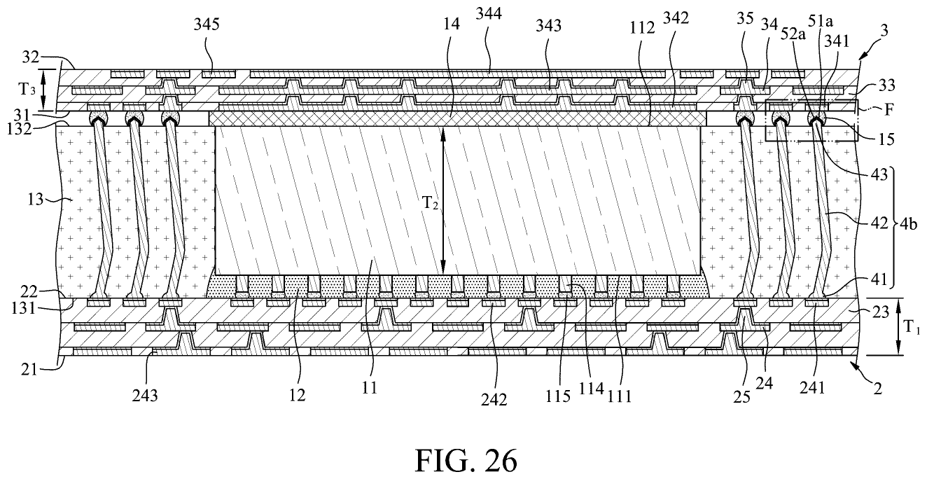

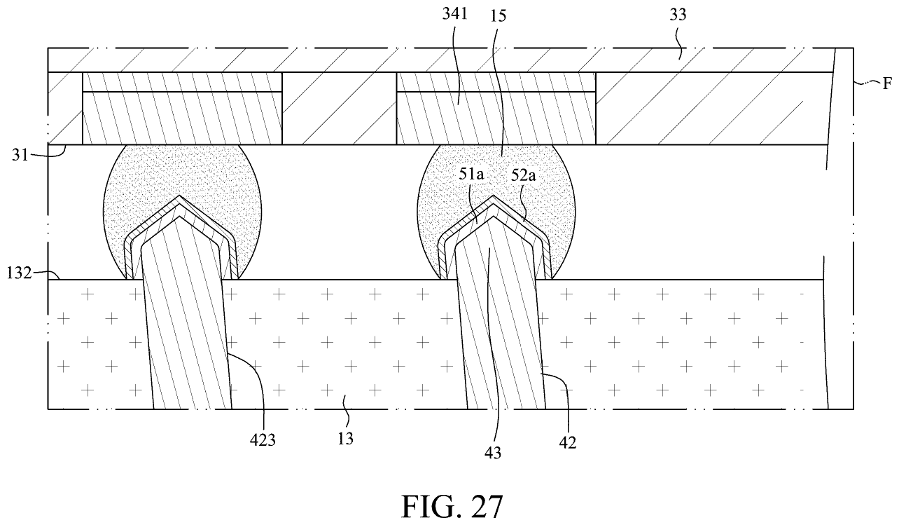

Referring to FIG. 26 and FIG. 27, wherein FIG. 27 illustrates an enlarged view of an area “F” of FIG. 26, an upper substrate 3 may be disposed over the lower substrate 2 and th e first electronic component 11. The upper substrate 3 of FIG. 26 may be the same as the upper substrate 3 of FIG. 5. The upper substrate 3 may be physically connected and electrically connected to the lower substrate 2 through the interconnection element(s) 4b and at least one solder material 15. The solder material 15 may include a re-flowable material such as SnAg alloy. The solder material 15 may electrically connect and physically connect the outer bond pad 341 of the upper substrate 3 and the second metal material 52. The solder material 15 may cover and contact the entire top surface of the second metal material 52. The solder material 15 may or may not contact the top surface 132 of the encapsulant 13.

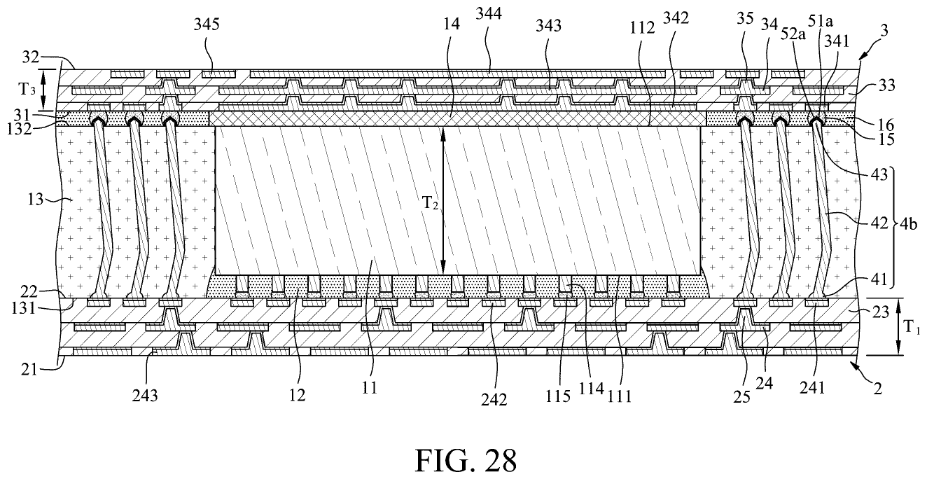

Referring to FIG. 28, a protection material 16 (e.g., an underfill) may be formed or disposed in the gap between the top surface 132 of the encapsulant 13 and the first surface 31 (the bottom surface) of the upper substrate 3 so as to cover and contact the solder materials 15.

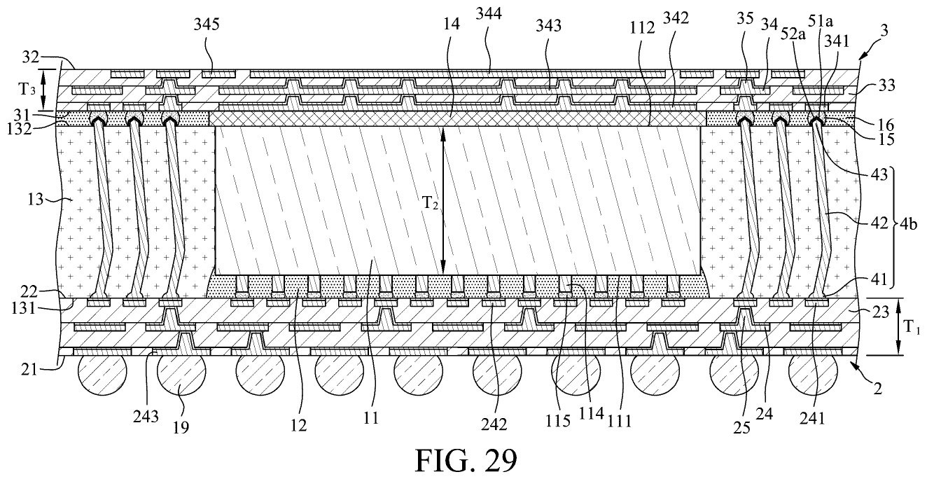

Referring to FIG. 29, at least one external connector 19 may be formed or disposed on the bottom pad 243 of the bottommost circuit layer 24 of the lower substrate 2 that is exposed by a bottom surface of the bottommost dielectric layer 23 (i.e., the first surface 21 (the bottom surface) of the lower substrate 2). The at least one external connector 19 may include a plurality of external connectors 19 for external connection. The external connector 19 may include a re-flowable material such as SnAg alloy.

Then, a second electronic component 17 may be disposed over the upper substrate 3. The second electronic component 17 may be electrically connected and physically connected to the top pad 345 of the upper substrate 3 through at least one connecting element 18. The connecting element 18 may include a solder material or a re-flowable material such as SnAg alloy. The function of the second electronic component 17 may be different from the function of the first electronic component 11.

Then, a singulation process may be conducted to obtain a plurality of electronic package structures 1b of FIG. 5 and FIG. 6.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic package structure, comprising:
an encapsulant;
an interconnection element disposed in the encapsulant, wherein a top surface of the interconnection element is not level with a top surface of the encapsulant;
a first metal material disposed on the top surface of the interconnection element; and
a second metal material conformally disposed on the first metal material.

2. The electronic package structure of claim 1, wherein the top surface of the interconnection element is lower than the top surface of the encapsulant, and the first metal material extends beyond the top surface of the encapsulant.

3. The electronic package structure of claim 2, wherein the interconnection element includes a conductive wire.

4. The electronic package structure of claim 3, wherein the interconnection element has a substantially consistent width, and is bent.

5. The electronic package structure of claim 2, wherein the second metal material contacts the top surface of the encapsulant.

6. The electronic package structure of claim 2, wherein the first metal material includes an upper portion and a lower portion, wherein a maximum width of the upper portion of the first metal material is greater than a maximum width of the lower portion of the first metal material, the maximum width of the lower portion of the first metal material is substantially equal to a width of the interconnection element, and the upper portion of the first metal material tapers away from the top surface of the encapsulant.

7. The electronic package structure of claim 6, wherein the upper portion of the first metal material includes a central portion and a periphery portion surrounding the central portion, wherein the central portion has a substantially consistent thickness and has a substantially flat top surface, wherein the periphery portion tapers away from the central portion.

8. The electronic package structure of claim 7, wherein a width of the substantially flat top surface of the central portion of the upper portion of the first metal material is substantially equal to a width of the interconnection element.

9. The electronic package structure of claim 2, further comprising:
an upper substrate; and
a solder material electrically connecting the upper substrate and the second metal material.

10. The electronic package structure of claim 9, further comprising:
an electronic component electrically connected to the lower substrate and encapsulated by the encapsulant, wherein a top surface of the electronic component is exposed by the encapsulant.

11. The electronic package structure of claim 10, further comprising:
a heat dissipation structure disposed on the top surface of the electronic component.

12. The electronic package structure of claim 11, wherein a bottom surface of the upper substrate directly contacts the heat dissipation structure.

13. The electronic package structure of claim 1, wherein an upper portion of the interconnection element extends beyond the top surface of the encapsulant.

14. The electronic package structure of claim 13, wherein both of the first metal material and the second metal material contact the top surface of the encapsulant.

15. The electronic package structure of claim 14, wherein the upper portion of the interconnection element tapers away from the top surface of the encapsulant.

16. The electronic package structure of claim 15, wherein the interconnection element further includes a main portion disposed in the encapsulant, wherein a turning point is formed between the upper portion of the interconnection element and the main portion of the interconnection element.

17. An electronic package structure, comprising:
an encapsulant;
an interconnection element disposed in the encapsulant, and being bent;
a first metal material disposed on an upper portion of the interconnection element;
a second metal material conformally disposed on the first metal material; and
a solder material disposed on the second metal material.

18. The electronic package structure of claim 17, wherein a top surface of the interconnection element is lower than a top surface of the encapsulant, and the first metal material extends beyond the top surface of the encapsulant.

19. An electronic package structure, comprising:
an encapsulant;
an interconnection element disposed in the encapsulant; and
an upper substrate disposed over the interconnection element, and including an outer bond pad, wherein a center of the outer bond pad is misaligned with a center of a top surface of the interconnection element in a direction perpendicular to a top surface of the encapsulant.

20. The electronic package structure of claim 19, further comprising a solder material disposed on the second metal material and connecting to the outer bond pad.
